(19) United States
(12) Patent Application Publication
(10) Pub. No.: US 2015/0221516 A1
(43) Pub. Date: Aug. 6, 2015

(54) PROCESS-COMPATIBLE SPUTTERING TARGET FOR FORMING FERROELECTRIC MEMORY CAPACITOR PLATES

(71) Applicant: Texas Instruments Incorporated, Dallas, TX (US)

(72) Inventors: Mark Robert Visokay, Dallas, TX (US); Scott Robert Summerfelt, Garland, TX (US)

(21) Appl. No.: 14/682,944

(22) Filed: Apr. 9, 2015

Related U.S. Application Data
(62) Division of application No. 14/088,572, filed on Nov. 25, 2013.
(60) Provisional application No. 61/729,897, filed on Nov. 26, 2012.

(51) Int. Cl. H01L 21/285; H01L 21/3213; C23C 14/08; C22C 32/00; B22F 3/10; B22F 5/00; C22C 28/00; H01L 49/02; C23C 14/34

(52) U.S. Cl. CPC H01L 21/2855; H01L 28/65; H01L 28/75; H01L 21/32133; C23C 14/08; C23C 14/3414; C23C 14/082; B22F 3/10; B22F 5/00; C22C 28/00; C22C 32/001; C22C 32/0031; C22C 32/0042; C22C 32/0015

(57) ABSTRACT

A sputtering target for a conductive oxide, such as SrRuO₃, to be used for the sputter deposition of a conductive film that is to be in contact with a ferroelectric material in an integrated circuit. The sputtering target is formed by the sintering of a powder mixture of the conductive oxide with a sintering agent of an oxide of one of the constituents of the ferroelectric material. For the example of lead-zirconium-titanate (PZT) as the ferroelectric material, the sintering agent is one or more of a lead oxide, a zirconium oxide, and a titanium oxide. The resulting sputtering target is of higher density and lower porosity, resulting in an improved sputter deposited film that does not include an atomic species beyond those of the ferroelectric material deposited adjacent to that film.

### CROSS-REFERENCE TO RELATED APPLICATIONS

This application is a divisional of U.S. patent application Ser. No. 14/058,572 filed Nov. 25, 2013, which claims priority, under 35 U.S.C. §119(e), of Provisional Application No. 61/729,897, filed Nov. 26, 2012, the contents of both are incorporated herein by this reference.

### STATEMENT REGARDING FEDERALLY SPONSORED RESEARCH OR DEVELOPMENT

Not applicable.

### BACKGROUND OF THE INVENTION

This invention is in the field of integrated circuit manufacture. Embodiments of this invention are more specifically directed to the formation of capacitor plates in memory devices such as ferroelectric memories.

Conventional metal-oxide-semiconductor (MOS) and complementary MOS (CMOS) logic and memory devices are prevalent in modern electronic devices and systems, as they provide an excellent combination of fast switching times and low power dissipation, along with their high density and suitability for large-scale integration. As is fundamental in the art, however, those devices are essentially volatile, in that logic and memory circuits constructed according to these technologies do not retain their data states upon removal of bias power. Especially in mobile and miniature systems, the ability to store memory and logic states in a non-volatile fashion is very desirable. As a result, various technologies for constructing non-volatile devices have been developed in recent years.

A recently developed technology for realizing non-volatile solid-state memory devices involves the construction of capacitors in which the dielectric material is a polarizable ferroelectric material, such as lead-zirconium-titanate (PZT) or strontium-bismuth-tantalate (SBT), rather than silicon dioxide or silicon nitride as typically used in non-ferroelectric capacitors. Hysteresis in the charge-vs.-voltage (Q-V) characteristic, based on the polarization state of the ferroelectric material, enables the non-volatile storage of binary states in those capacitors. In contrast, conventional MOS capacitors lose their stored charge on power-down of the device. It has been observed that ferroelectric capacitors can be constructed by processes that are largely compatible with modern CMOS integrated circuits, for example placing capacitors above the transistor level, between overlying levels of metal conductors.

Non-volatile solid-state read/write random access memory (RAM) devices based on ferroelectric capacitors, such memory devices commonly referred to as “ferroelectric RAM”, or “FeRAM”, or “FRAM” devices, have been implemented in many electronic systems, particularly portable electronic devices and systems. FeRAMs are especially attractive in implantable medical devices, such as pacemakers and defibrillators. Various memory cell architectures including ferroelectric capacitors are known in the art, including the well-known 2T2C (two transistor, two capacitor) cells. Another type of FeRAM cell is based on the well-known “6T” CMOS static RAM cell, which operates as an SRAM cell during normal operation, but in which ferroelectric capacitors coupled to each storage node can be programmed with the stored data state to preserve memory contents in non-volatile fashion. Ferroelectric capacitors are also implemented in some integrated circuits as programmable analog capacitors.

In early FRAM devices, the capacitor plates, or electrodes, of the ferroelectric capacitors were formed of conductive metal films, such as platinum. However, in recent years, conductive oxides are now often used as the material for the capacitor plates. One example of a conductive oxide now used as the capacitor plate (both top and bottom) material of conventional ferroelectric capacitors is strontium ruthenate (SrRuO₃). Due to its perovskite crystal structure and its lattice constant, both of which are similar to the PZT ferroelectric material, SrRuO₃ has been observed to provide a smoother surface for the bottom electrode, and better growth of the PZT material as it is deposited. In particular, it has been observed that the deposited PZT film is itself smoother as a result of the smoother SrRuO₃ lower plate, which facilitates the scaling of the PZT film to reduced thicknesses. The SrRuO₃ material or other conductive oxide is typically used for both the bottom and top plates of the ferroelectric capacitor, for these structural benefits and for symmetry. In addition, as reported in Morimoto et al., “Ferroelectric Properties of Pb(Zr,Ti)O3 Capacitor with Thin SrRuo3 Films within Both Electrodes”, Jpn. J. AppL Phys., Vol. 39 (April 2000), pp. 2110-2113, the use of SrRuO₃ as the material of one or both of the bottom and top plates has been observed to improve the ferroelectric polarization in PZT capacitors as compared with platinum as the electrode material, with the most improvement obtained in the case of both the bottom and top plates formed of SrRuO₃.

In the manufacture of integrated circuits using these ferroelectric capacitors, the SrRuO₃ film is typically deposited by sputter deposition. As fundamental in the art, sputter deposition of a film is performed by bombarding a solid “target” with particles of sufficient energy to cause atoms or molecules to be ejected from the target. The ejected atoms or molecules then deposit onto the desired substrate surface. The target must, of course, be constituted of the material that is desired to be deposited. Typical sputtering targets are in the form of a thin, flat, solid disk or ring of the material to be deposited, of a diameter equal or larger to that of the substrate to be coated. In order to form high quality thin sputtered films that are suitable for use in semiconductors, the sputtering targets ought to have minimum voids, grooves, grain boundaries, and other non-uniformities, and thus of high material density. Sputtering targets for metals are often formed by cooling the molten metal into the desired shape of the target, to attain the desired high density. Some sputtering targets are formed by sintering, which can also attain a suitable density for use as a sputtering target, depending on the “sinterability” of the material at reasonable temperatures.

Complex materials such as SrRuO₃ and other conductive oxides and ceramics are typically formed into a sputtering target by sintering particles of that material. However, these ceramics are generally high temperature materials, and as such are not suitable for melting and cooling into a high density (i.e., low porosity) sputtering target. In addition, these materials generally exhibit poor sinterability. As such, sputtering targets of SrRuO₃ and similar ceramics and conductive oxides tend to be of low density, especially at the sizes required for modern integrated circuit fabrication using wafers having diameters of 300 mm or greater.

By way of further background, the use of sintering auxiliary agents for increasing the sintering density of materials is known. One known example of such a sintering agent for the formation of a sputtering target of SrRuO₃ is bismuth oxide (Bi₂O₃). It has been observed, however, that the Bi₂O₃ sintering agent can form a bismuth compound at the surface of the deposited film, which can deteriorate the dielectric properties of ferroelectric material overlying that film.

In addition, as known in the art, the introduction of a new atomic species into an integrated circuit fabrication facility and process flow is generally problematic. The effects of the introduced species on the yield and reliability of the integrated circuits being produced is typically unknown, and must be determined through qualification testing. In addition, the introduced species can require evaluation from a safety and environmental standpoint.

### BRIEF SUMMARY OF THE INVENTION

Embodiments of this invention provide a sputtering target of a conductive oxide, and methods of forming such a target and using the target in the manufacture of integrated circuits, that is compatible with complex dielectric materials such as ferroelectric dielectrics.

Embodiments of this invention provide such a target that is of high density, and suitable for the sputter deposition of films onto modern large diameter semiconductor wafers.

Embodiments of this invention provide such a target and methods that do not introduce additional atomic species into the manufacturing facility or process flow.

Other objects and advantages of embodiments of this invention will be apparent to those of ordinary skill in the art having reference to the following specification together with its drawings.

Embodiments of this invention may be implemented into the formation and use of a sputtering target for a conductive oxide, such as SrRuO₃, to be used for the sputter deposition of a conductive film that is to be in contact with a ferroelectric material, such as PZT, in an integrated circuit. The sputtering target is formed by the sintering of the conductive oxide material in combination with an additive of a compound of one of the constituents of the ferroelectric material. The additive serves as a sintering agent, to produce a higher density, lower porosity, sintered body in the desired form for use as the sputtering target.

### BRIEF DESCRIPTION OF THE SEVERAL VIEWS OF THE DRAWING

FIG. 1 is a cross-sectional view of a portion of an integrated circuit including a ferroelectric capacitor at a selected stage of manufacture according to embodiments of this invention.

FIG. 2 is a flow diagram illustrating a process of forming a ferroelectric capacitor according to embodiments of this invention.

### DETAILED DESCRIPTION OF THE INVENTION

This invention will be described in connection with its embodiments, namely as used in the manufacture of semiconductor integrated circuits that include dielectric films of particular ferroelectric or piezoelectric properties, as it is contemplated that this invention is especially beneficial when used in such applications. However, it is contemplated that those skilled in the art having reference to this specification will recognize the benefits and advantages of this invention beyond those applications. Accordingly, it is to be understood that the following description is provided by way of example only, and is not intended to limit the true scope of this invention as claimed.

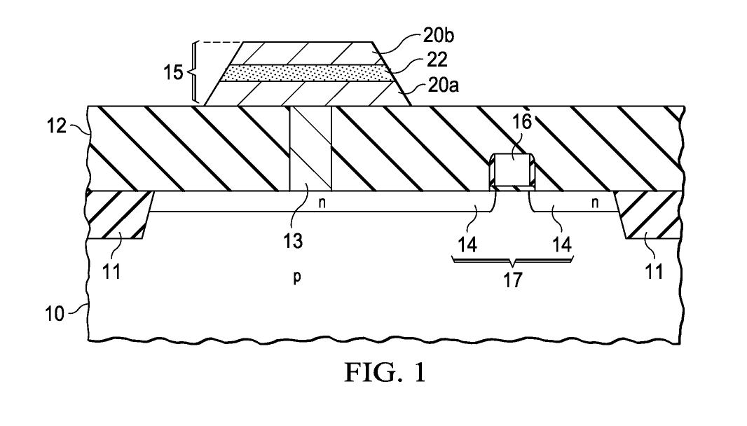

For purposes of context, FIG. 1 illustrates, in cross-section, a portion of an integrated circuit including a portion of a ferroelectric random access memory (FRAM), as may be constructed using embodiments of the invention. In this example, ferroelectric capacitor 15 and metal-oxide-semiconductor (MOS) transistor 17 are disposed at or near a semiconducting surface of a semiconductor substrate. Alternatively, embodiments of this invention may be used to form transistors, capacitors, and other semiconductor structures at or near the surface of a semiconductor layer that itself overlies an insulator layer, such as according to a silicon-on-insulator (SOI) technology as known in the art.

In the example of the integrated circuit shown in FIG. 1, isolation dielectric structures 11, gate electrode 16, and n-type source/drain regions 14 are disposed at or near the surface of substrate 10, in the conventional manner for MOS integrated circuits, as well-known in the art. N-channel MOS transistor 17 in the example of FIG. 1 includes n-type source/drain regions 14 at the surface of p-type substrate 10 (or of a p-type “well” formed into substrate 10, as the case may be), with gate electrode 16 overlying a channel region between source/drain regions 14, and separated from the channel region by a gate dielectric, as conventional. Interlevel dielectric 12 is disposed over transistor 17, with conductive plug 13 disposed in a contact opening through interlevel dielectric 12 to provide a conductive connection between one of source/drain regions 14 of transistor 17 and lower plate 20a of ferroelectric capacitor 15.

Ferroelectric capacitor 15, in the example of FIG. 1, is formed of a ferroelectric “sandwich” stack of conductive plates 20a, 20b, between which ferroelectric material 22 is disposed. Bottom plate 20a is formed at a location overlying conductive plug 13, as shown in FIG. 1, so as to be in electrical contact with the underlying source/drain region 14 by way of conductive plug 13.

According to an embodiment of the invention, ferroelectric material 22 is lead-zirconium-titanate, which is commonly referred to as PZT. As known in the art, PZT has a perovskite crystalline structure, which is typically cubic. It is desirable for ferroelectric material 22 in capacitor 15 to be as thin as practicable, for purposes of electrical performance (e.g., capacitance), and for consistency with the deep sub-micron features used to realize modern integrated circuits. As known in the art, it is desirable to form lower conductive plate 20a of a conductive material that has a similar perovskite crystal structure, and a similar lattice constant (i.e., distance between unit cells in the crystal lattice), as that of the PZT ferroelectric material 22. As discussed above in connection with the Background of the Invention, strontium ruthenate (SrRuO₃) is a conductive oxide that has a similar perovskite crystal structure and lattice constant as PZT. SrRuO₃ has been observed to provide a smooth and compatible surface upon which to deposit a smooth and uniform PZT film. In the structure of FIG. 1 and according to embodiments of this invention, both lower conductive plate 20a and upper conductive plate 20b are formed of SrRuO₃, for purposes of symmetry, simplicity of the manufacturing flow, and improved ferroelectric polarization performance.

According to embodiments of this invention, the SrRuO₃ material of lower and upper conductive plates 20a, 20b will typically be in direct contact with ferroelectric material 22 to obtain the improved PZT properties as described above. It is also contemplated that a layer of alternative materials may be deposited between plates 20a, 20b, and contacts below or vias above ferroelectric capacitor 15, according to embodiments of this invention. For example, one or more layers of a conducting material, such as noble metals such as Ru, Pt, Ir, Rh, Pt, Pd, Au, noble metal oxides (RuOx, IrOx, PdOx, etc.) with an additional conductive diffusion barrier such as TiN, TiAlN, TiAlON, TaSiN, CrN, HfN, TaN, HfAlN, CrAlN, TiSiN, CrSiN, or similar combinations, may be formed between the top surface of SrRuO₃ upper conductive plate 20b and conductors (not shown) that contact plate 20b through a via in an overlying insulator layer, and between lower conductive plate 20a and the underlying conductive plug 13. Examples of stacks according to this construction include the layers (listed from bottom to top) of: TiN/TiAlON/Ir or Ru/SrRuO₃ (plate 20a)/PZT (ferroelectric material 22)/SrRuO₃ (plate 20b)/IrOx or RuOx/Ir or Ru/TiAlON.

Further in the alternative, it is also contemplated that the SrRuO₃ material of lower and upper conductive plates 20a, 20b may include some amount of calcium or barium (or both) impurities, to obtain such benefits as better lattice mismatch or an induced preferential strain. According to this alternative implementation, the resulting material of lower and upper conductive plates 20a, 20b may be a compound of the form (Sr_{1-x-y}CaₓBa_{y})RuO₃.

As also discussed above in connection with the Background of the Invention, it is desirable to form lower and upper conductive plates 20a, 20b by sputter deposition. However, as known in the art, the sputter deposition of a thin, high quality film necessitates a high density (low porosity) sputtering target, of a size greater than the diameter of the wafer, is not readily attainable for strontium ruthenate and other conductive oxides and ceramics, due to the low sinterability of those materials. In particular, conventional sputtering targets formed by the sintering of pure strontium ruthenate and other ceramics tend to be of high porosity and thus low density, with voids, grooves, distinct grain boundaries, and other defects. While it is known to include bismuth oxide as a sintering agent in the fabrication of strontium ruthenate sputtering targets, this agent can result in the formation of a bismuth compound at the surface of the deposited strontium ruthenate film, which can deteriorate the dielectric properties of ferroelectric material overlying that film. In most modern MOS process flows, the bismuth from the sintering target will be a new atomic species that is introduced into the integrated circuit manufacturing flow and facility, which raises issues regarding other effects on the devices being produced, as well as health and environmental concerns.

According to embodiments of the invention, the sputtering targets used for the sputter deposition of lower and upper conductive plates 20a, 20b of capacitor 15 are formed by the sintering of strontium ruthenate (SrRuO₃) in combination with an additive sintering agent that is based on a component of the material ferroelectric material 22 that is to be in contact with lower and upper conductive plates 20a, 20b. In this embodiment of the invention in which PZT constitutes ferroelectric material 22, the sintering agent is an oxide of one of the components of the PZT material, namely one or more of a lead oxide (e.g., PbO), a titanium oxide (e.g., TiO₂), or a zirconium oxide (e.g., ZrO₂). It is contemplated that lead oxide (PbO) is the most desirable of the three, but any one or more of these oxides of the components of the PZT may be used as the sintering agent.

According to this embodiment of the invention, the manufacture of a sputtering target of strontium ruthenate with one of these sintering agents of an oxide of a component of ferroelectric material 22 may performed in the conventional manner. A powder of strontium ruthenate is prepared in the conventional manner, for example by the thermal synthesis that occurs in the dehydration of a slurry mixture of SrCO₃ powder and RuO₂ powder. A powder of the desired sintering agent, namely one or more of a lead oxide, a titanium oxide, or a zirconium oxide, is then added to and mixed with the strontium ruthenate powder. It is contemplated that the amount of the sintering agent powder that is mixed in with the strontium ruthenate powder will be of a similar amount as conventional sintering agents, for example at least 0.3 mol % and ranging up to on the order of 20 mol % for the case of lead oxide (PbO). It is contemplated that those skilled in the art having reference to this specification will be able to determine the optimum concentration of the sintering agent in the resulting powder mixture, for each particular application and use, without undue experimentation.

Following the mixing of the strontium ruthenate powder with the sintering agent powder, the mixture is packed into a mold of the desired size and shape corresponding to the eventual sintering target. Typical sintering targets are in the shape of a disk or ring, having a diameter somewhat greater than the diameter of the semiconductor wafer onto which the sputtered film is to be deposited. For the example of a 300 mm wafer, it is contemplated that the eventual sputtering target will be on the order of 400 cm in diameter. An organic binder may be added to the powder mixture if desired, for the case in which the packing of the powder mixture is performed by press molding (e.g., cold isostatic pressing).

The packed powder mixture, in the desired shape and size, is then sintered in the conventional manner. As known in the art, useful sintering temperatures for strontium ruthenate range from on the order of 1400 deg C. to on the order of 1700 deg C. The upper limit of the sintering temperature is the temperature at which evaporation of ruthenium oxide (RuO₂) becomes significant. Conventional cleaning and removal of surface layers and contaminants is then performed, to provide the sintering target.

As mentioned above, the use of a bismuth oxide sintering agent in the formation of conventional strontium ruthenate sintering targets may result in the formation of a bismuth compound at the surface of the deposited strontium ruthenate film. As described in U.S. Pat. No. 7,252,794, the potential of this bismuth compound and its ability to deteriorate an overlying ferroelectric material forces an upper limit on the amount of bismuth oxide sintering agent that can be used in the formation of a strontium ruthenate sintering target. In contrast, it is contemplated that embodiments of this invention in which the sintering agent is an oxide of one of the components of the ferroelectric material will not suffer from this vulnerability, since any such collateral reaction products from the sintering agent that appear at the surface of the deposited strontium ruthenate film will be formed of a constituent of the ferroelectric film itself. As a result, it is contemplated that the upper limit of the concentration of the sintering agent in the powder mixture used to form the sintering target will be much higher than that of the conventional bismuth oxide sintering agent. Accordingly, it is contemplated that embodiments of this invention may provide improved sintering of the strontium ruthenate powder, by allowing the amount of sintering agent in the powder mixture to be selected for optimum sinterability, without being limited by the contamination risk of bismuth oxide.

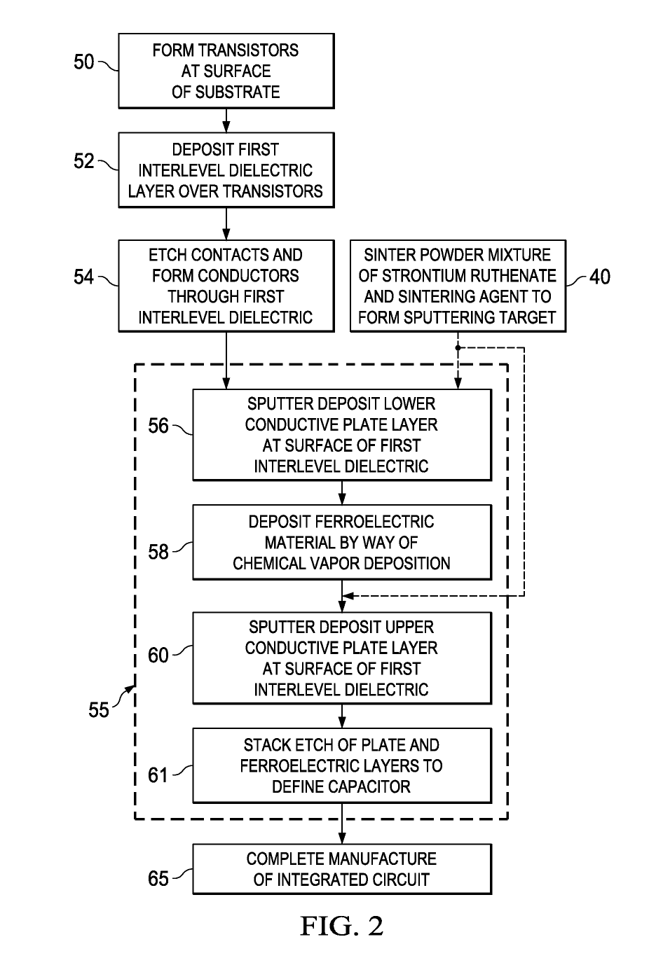

Once the sintering target of strontium ruthenate has been formed according to an embodiment of the invention, an integrated circuit including a ferroelectric capacitor having strontium ruthenate conductive plates on opposite sides of PZT ferroelectric material may be fabricated. A process for manufacturing an integrated circuit including ferroelectric capacitor 15 of FIG. 1 according to embodiments of this invention, by way of example, will now be described with reference to FIG. 2.

In process 50, transistors such as transistor 17 are formed at or near the semiconducting surface of substrate 10 or other support body, in the conventional manner. As pat of process 50, isolation dielectric structures 11, the appropriate doped wells (not shown), gate dielectric layer, gate electrodes 16, and source/drain regions 14, among other structures, are formed at or near the surface of substrate 10 according to conventional MOS processes. N-channel MOS transistor 17 shown in FIG. 1 may be formed in the conventional manner by deposition and photolithographic patterning and etch of polysilicon material to define gate electrode 16 overlying a gate dielectric, with n-type source/drain regions 14 formed on either side of gate electrode 16 by ion implantation and subsequent activation anneal, in the well-known self-aligned manner.

In process 52, first interlevel dielectric 12 is then deposited over the transistors such as transistor 17 that were formed in process 50, for example by way of chemical vapor deposition, followed by planarization if desired. In process 54, contact openings (i.e., vias) are etched through first interlevel dielectric 12 at selected locations, and conductive plugs 13 are formed into those openings in the conventional manner to provide an electrical contact between one of source/drain regions 14 of MOS transistor 17 and the eventual ferroelectric capacitor 15. Conductive plug 13 may be formed of a metal such as tungsten, titanium, and the like, or an alloy thereof,

Following the formation of the first interlevel dielectric layer in process 52, and the contact etch and conductor formation in process 54, ferroelectric capacitor 15 is formed in the integrated circuit in process 55 according to this embodiment of the invention. Process 55 begins with the sputter deposition of a layer of strontium ruthenate (SrRuO₃) to the desired thickness overall, at the surface of first interlevel dielectric 12 and overlying conductive plug 13, in process 56. According to embodiments of this invention, sputter deposition process 56 is performed from a sputtering target formed, in process 40 shown in FIG. 2, in the manner described above from a sintered powder mixture of strontium ruthenate with a sintering agent additive of a constituent of ferroelectric material 22 to be deposited, for example one or more of a lead oxide, a titanium oxide, and a zirconium oxide.

Following the deposition of the layer of strontium ruthenate in process 56, ferroelectric material 22 is deposited overall in process 58. It is contemplated that ferroelectric material 22, which is PZT in this example, will be deposited in process 58 by way of chemical vapor deposition. Alternatively, other approaches for the deposition of PZT ferroelectric material 22 may be used in process 58, for example, sputter deposition.

A second, upper, layer of strontium ruthenate (SrRuO₃) is then sputter deposited to the desired thickness overlying ferroelectric material 22, in process 60. It is contemplated that, according to embodiments of this invention, sputter deposition process 60 is similarly performed from a sputtering target formed in process 40 and described above, using a sputtering target formed from a sintered powder mixture of strontium ruthenate with a sintering agent additive of a constituent of ferroelectric material 22 to be deposited, for example one or more of a lead oxide, a titanium oxide, and a zirconium oxide.

In process 61, ferroelectric capacitor 15 is then completed by the photolithographic patterning to define its size and location, and a single stack etch of conductive plates 20a, 20b, and ferroelectric material 22. Commonly assigned U.S. Pat. No. 6,656,748, incorporated herein by reference, describes an example of ferroelectric stack formation and etch process 61, suitable for use in connection with embodiments of this invention. Additional processing to complete ferroelectric capacitor 15, such as the formation of passivation films such as described in commonly assigned copending U.S. patent application Ser. No. 13/432,736, incorporated herein by this reference, may also be performed. The manufacture of the integrated circuit is then completed in process 65, by conventional processes for forming the various levels of interlevel dielectrics, conductors, and the like.

According to this embodiment of the invention, the formation of a high density, low porosity, sputtering target of strontium ruthenate is enabled, without involving the use of a sintering agent that can degrade the eventual ferroelectric material to be deposited over a film that is sputter deposited from that sputtering target. The resulting ferroelectric capacitor formed with conductive plates sputter deposited from such a sputtering target is contemplated to have excellent smoothness and compatibility in its conductive plates and ferroelectric material, and because of this smoothness, to be well-suited for scaling the ferroelectric material to reduced thicknesses and thus attaining the corresponding improvement in electrical performance of the device. Introduction of a foreign atomic species into the manufacturing process flow and facility is also avoided according to this embodiment of the invention.

Another advantage provided by embodiments of this invention, in which one or more of the components of the ferroelectric material serves as a sintering agent in the sputtering target, results from interdiffusion of the different chemical compounds in the sputtering target material. For example, it is believed that a small amount of Pb in the sputtered SrRuO₃ material of lower conductive plate 20a will likely reduce the amount of Pb that might diffuse out of the adjacent PZT ferroelectric material 22, providing better composition control of ferroelectric material 22 and thus improved electrical properties of capacitor 15. On the other hand, a sintering agent of a component not present in the ferroelectric material, such as the bismuth additive that is conventionally used, leads to the risk that this component would itself diffuse from the sputtered SrRuO3 capacitor plates, and contaminate or modify the PZT composition of the overlying ferroelectric. More specifically, it is contemplated that Bi⁺³ from the sputtered film would diffuse from the capacitor plates and become likely to sit on the Pb⁺² lattice site in the ferroelectric, acting as an acceptor impurity. As known in the art, acceptor impurities tend to create oxygen vacancies, which is undesirable in PZT ferroelectric material particularly when used in memory applications.

Other embodiments of this invention as useful in other material systems, are also contemplated. One such embodiment contemplated by this invention is directed to a ferroelectric capacitor in which the ferroelectric material is strontium-bismuth-tantalate (SBT), and in which the conductive plates are formed of a sputter-deposited conductive oxide or ceramic having a similar crystal structure and lattice constant to that of the SBT ferroelectric film. An example of a conductive oxide useful with an SBT ferroelectric material is a platinum-rhodium-oxide. According to this alternative embodiment of the invention, a sputtering target for the deposition of the conductive plates is formed from a powder of the conductive oxide (e.g., PtRhOx) mixed with a powder of a sintering agent consisting of one or more of a strontium oxide, a bismuth oxide, and a tantalum oxide. This sputtering target is formed in the manner described above, including the packing of the powder mixture to the size and shape of the desired sputtering target, and the sintering of that packed powder mixture at the appropriate temperature.

It is further contemplated that this invention can be used in the formation of capacitors for integrated circuits that involve piezoelectric dielectric material. Barium titanate is an example of a suitable piezoelectric material. In this alternative embodiment of the invention, conductive plates are formed by sputter deposition of a conductive oxide or ceramic having a crystal structure and lattice constant similar to that of barium titanate, where the sputtering target is formed from a powder of that conductive oxide mixed with a powder of a sintering agent consisting of one or more of a barium oxide and a titanium oxide. In this embodiment of the invention, this sputtering target is formed in the manner described above, including the packing of the powder mixture to the size and shape of the desired sputtering target, and the sintering of that packed powder mixture at the appropriate temperature.

It is contemplated that the advantages described above will also be made available by the formation and use of sputtering targets according to these alternative embodiments of the invention. More specifically, it is contemplated that these embodiments of the invention enable the formation of high density, low porosity, sputtering targets of the desired conductive oxide or ceramic, without involving the use of a sintering agent that can degrade the eventual ferroelectric or piezoelectric material to be deposited over the sputter-deposited film from that sputtering target. In each case, the introduction of a foreign atomic species into the manufacturing process flow and facility is also avoided.

While this invention has been described according to its embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. A method of fabricating an integrated circuit including a ferroelectric capacitor, comprising the steps of:
depositing a first conductive film, comprising a conductive oxide, near a semiconducting surface of a body, by sputter deposition of the conductive oxide from a sputtering target;
depositing a ferroelectric material overlying the first conductive film, the ferroelectric material comprising a compound of a plurality of metal constituents;
depositing a second conductive film, comprising the conductive oxide, overlying the ferroelectric material; and
removing portions of the first and second conductive films, and the ferroelectric material, at selected locations, to define the ferroelectric capacitor;
wherein the sputtering target comprises a conductive oxide sintered body containing an oxide of one of the plurality of metal constituents of the ferroelectric material.

2. The method of claim 1, wherein the ferroelectric material comprises lead-zirconium-titanate.

3. The method of claim 2, wherein the oxide of one of the plurality of metal constituents of the ferroelectric material is selected from a group consisting of a lead oxide, a titanium oxide, and a zirconium oxide.

4. The method of claim 3, wherein the conductive oxide of the first and second conductive films comprises strontium ruthenate.

5. The method of claim 1, wherein the ferroelectric material comprises strontium-barium-titanate.

6. The method of claim 5, wherein the oxide of one of the plurality of metal constituents of the ferroelectric material is selected from a group consisting of a strontium oxide, a barium oxide, and a titanium oxide.

7. The method of claim 1, wherein the conductive oxide of the first and second conductive films comprises strontium ruthenate.

8. The method of claim 7, wherein the conductive oxide of the first and second conductive films comprises a compound of strontium ruthenate with either or both of calcium and barium.

9. The method of claim 7, wherein the step of depositing the second conductive film comprises:
sputter deposition of strontium ruthenate from a sputtering target comprising the conductive oxide sintered body containing the oxide of one of the plurality of metal constituents of the ferroelectric material.

10. The method of claim 1, further comprising:
prior to the step of depositing the first conductive film, depositing a conducting layer comprising a noble metal or noble metal oxide.

11. The method of claim 10, further comprising:
after the step of depositing the second conductive film, depositing a conducting layer comprising a noble metal or noble metal oxide.

12. The method of claim 1, further comprising:
after the step of depositing the second conductive film, depositing a conducting layer comprising a noble metal or noble metal oxide.

13. A sputtering target, comprising a sintered body of strontium ruthenate and a metal oxide selected from a group consisting of a lead oxide, a titanium oxide, and a zirconium oxide.

14. The sputtering target of claim 13, wherein the strontium ruthenate comprises a compound of strontium ruthenate with either or both of calcium and barium.

15. A method of forming a sputtering target, comprising:
mixing a powder of strontium ruthenate with a powder of metal oxide selected from a group consisting of a lead oxide, a titanium oxide, and a zirconium oxide; and
then sintering the mixed powder into a solid body.

16. The method of claim 15, wherein the strontium ruthenate comprises a compound of strontium ruthenate with either or both of calcium and barium.

17. A sputtering target, comprising a sintered body of a crystalline conductive oxide having a lattice constant matching that of strontium-bismuth-tantalate, and a metal oxide selected from a group consisting of a strontium oxide, a bismuth oxide, and a tantalum oxide.

18. A method of forming a sputtering target, comprising:
mixing a powder of a crystalline conductive oxide having a lattice constant matching that of strontium-bismuth-tantalate, with a powder of metal oxide selected from a group consisting of a strontium oxide, a bismuth oxide, and a tantalum oxide; and
then sintering the mixed powder into a solid body.
